(19) United States
(12) Patent Application Publication
(10) Pub. No.: US 2026/0204666 A1
(43) Pub. Date: Jul. 16, 2026

(54) BATTERY PACK

(71) Applicant: Nanjing Chervon Industry Co., Ltd., Nanjing (CN)

(72) Inventors: Yiwen Xiao, Nanjing (CN); Di Wu, Nanjing (CN); Cunrong Huang, Nanjing (CN); Zhongcao Hu, Nanjing (CN); Dong Yang, Nanjing (CN); Xianfeng Shao, Nanjing (CN); Guiwu Hu, Nanjing (CN)

(21) Appl. No.: 19/232,449

(22) Filed: Jun. 9, 2025

Related U.S. Application Data
(63) Continuation of application No. PCT/CN2025/072397, filed on Jan. 15, 2025.

(51) Int. Cl. H01M 10/42; G01R 31/385; G01R 31/389; H01M 10/44; H01M 50/204; H01M 50/247; H01M 50/296; H01M 50/505; H01M 50/519; H01M 50/522; H01M 50/569

(52) U.S. Cl. CPC H01M 10/4257; G01R 31/385; G01R 31/389; H01M 10/441; H01M 50/247; H01M 50/296; H01M 50/505; H01M 50/519; H01M 50/522; H01M 50/569; H01M 2010/4271; H01M 50/204; H01M 2200/105

(57) ABSTRACT

A battery pack includes a housing, a plurality of battery cells, a terminal assembly having a positive terminal and a negative terminal, and a bus bar electrically connecting the plurality of battery cells to the terminal assembly. A resistance value of the bus bar at 25° C. is less than or equal to 0.18 mΩ, and a resistance drift rate of the bus bar is less than or equal to 0.5 μΩ/° C. A distance between a temperature detector to sense the temperature of the bus bar and the bus bar is less than or equal to 5 mm. A controller is coupled to the temperature detector and configured to determine a resistance of the bus bar based on the temperature of the bus bar, and calculate a current of the battery pack based on the voltage and the resistance of the bus bar.

### RELATED APPLICATION INFORMATION

This application is a continuation of International Application Number PCT/CN2025/072397, filed on Jan. 15, 2025, which application is incorporated herein by reference in its entirety.

### TECHNICAL FIELD

The present application relates to the technical field of a battery or a battery pack, for example, a battery pack for a power tool.

### BACKGROUND

Batteries or battery packs are widely used among electrical device, such as power tools, computers, electrical vehicles, etc. Cordless power tools are typically powered by portable battery packs. Currents of the battery packs, including charging currents, discharging currents and the like, always need to be obtained and used to determine a certain control method executed by a controller inside the battery packs.

This part provides background information related to the present application, and the background information is not necessarily the existing art.

### SUMMARY

A battery pack includes a housing, a plurality of battery cells, a terminal assembly having a positive terminal and a negative terminal, and a bus bar electrically connecting the plurality of battery cells to the terminal assembly. A resistance value of the bus bar under normal room temperature is less than or equal to 0.18 mΩ, and a resistance drift rate of the bus bar is less than or equal to 0.5 μΩ/° C. A distance between a temperature detector to sense the temperature of the bus bar and the bus bar is less than or equal to 5 mm. A controller is coupled to the temperature detector and configured to determine a resistance of the bus bar based on the temperature of the bus bar, and calculate a current of the battery pack based on the voltage and the resistance of the bus bar.

A battery pack includes a housing connectable to and supportable by a power tool; a plurality of battery cells supported within the housing; a terminal assembly disposed on the housing and configured to electrically connect the battery pack to the power tool, the terminal assembly comprising a positive terminal and a negative terminal; and a bus bar electrically connecting the plurality of battery cells to the positive terminal or the negative terminal; a resistance value of the bus bar under normal room temperature is less than or equal to 0.18 mΩ, and a resistance drift rate of the bus bar is less than or equal to 0.5 μΩ/° C.

A battery pack includes a housing connectable to and supportable by a power tool; a plurality of battery cells supported within the housing; a terminal assembly disposed on the housing and configured to electrically connect the battery pack to the power tool, the terminal assembly comprising a positive terminal and a negative terminal; a bus bar electrically connecting the plurality of battery cells to the positive terminal or the negative terminal; and a temperature detector configured to detect a temperature of the bus bar, wherein a distance between the temperature detector and the bus bar is less than or equal to 5 mm.

A battery pack includes a housing connectable to and supportable by a power tool; a plurality of battery cells supported within the housing; a terminal assembly disposed on the housing and configured to electrically connect the battery pack to the power tool, the terminal assembly comprising a positive terminal and a negative terminal; a bus bar electrically connecting the plurality of battery cells to the positive terminal or the negative terminal; a detection circuit configured to detect a voltage of the bus bar; a temperature detector configured to detect a temperature of the bus bar; and a controller coupled to the detection circuit and the temperature detector, the controller being configured to: receive the temperature of the bus bar from the temperature detector and the voltage of the bus bar from the detection circuit; determine a resistance of the bus bar based on the temperature of the bus bar; calculate a charge and/or discharge current of the battery pack based on the voltage and the resistance of the bus bar; and control a charge and/or discharge process of the plurality of battery cells based on the charge and/or discharge current.

In one example, a conduction rate of the bus bar is greater than or equal to 80%IACS.

In one example, a main material of the bus bar is T2 red copper.

In one example, the battery pack further includes a temperature detector configured to detect a temperature of the bus bar.

In one example, the battery pack further includes a detection circuit configured to detect a voltage of the bus bar.

In one example, the battery pack further includes a controller, the controller is configured to: receive the temperature of the bus bar from the temperature detector and the voltage of the bus bar from the detection circuit; determine a resistance of the bus bar based on the temperature of the bus bar; calculate a charge/discharge current of the battery pack based on the voltage and the resistance of the bus bar; and control a charge/discharge process of the plurality of battery cells based on the charge/discharge current.

In one example, the temperature detector is an Negative Temperature Coefficient (NTC) thermistor.

In one example, the temperature detector is adhered to the bus bar by a thermally conductive adhesive.

In one example, a thermal conductivity of the thermally conductive adhesive is greater than or equal to 0.8 W/(m*K).

In one example, the temperature detector is in direct contact with the bus bar.

In one example, a distance between the temperature detector and the bus bar is less than or equal to 5 mm.

In one example, a distance between the temperature detector and the bus bar is less than or equal to 3 mm.

In one example, the battery pack further includes a printed circuit board supported within the housing, wherein the temperature detector is located in between the printed circuit board and the bus bar.

In one example, a resistance error of the bus bar is less than 10%.

In one example, a resistance error of the bus bar is less than 6%.

### BRIEF DESCRIPTION OF THE DRAWINGS

FIG. 1 is an overall structural view of a first example of the battery pack.

FIG. 2 is an inside structural inside view with of the example in FIG. 1 with a housing being removed.

FIG. 3 is a structural view of a printed circuit board and a terminal assembly of the example in FIG. 2.

FIG. 4 is a top view of the structure shown in FIG. 4.

FIG. 5 is a view of the structure shown in FIG. 3 when observing in a different viewing angle.

FIG. 6 is a structural view of a bus bar shown in the FIGS. 1-5.

FIG. 7 is a control method executed by a controller in the battery pack shown in the FIGS. 1-5.

FIG. 8 is a detection circuit diagram of a second example to show the principle of voltage detection and current calculation.

FIG. 9 is an inside structural view of a terminal assembly, a printed circuit board and a bus bar of the second example.

FIG. 10 is a top view of the structure shown in FIG. 9.

FIG. 11 is a section view of FIG. 4 in A-A direction

FIG. 12 is a section view of FIG. 10 in B-B direction.

### DETAILED DESCRIPTION

Before any examples of this application are explained in detail, it is to be understood that this application is not limited to its application to the structural details and the arrangement of components set forth in the following description or illustrated in the above drawings.

In this application, the terms “comprising”, “including”, “having” or any other variation thereof are intended to cover an inclusive inclusion such that a process, method, article or device comprising a series of elements includes not only those series of elements, but also other elements not expressly listed, or elements inherent in the process, method, article, or device. Without further limitations, an element defined by the phrase “comprising a . . . ” does not preclude the presence of additional identical elements in the process, method, article, or device comprising that element.

In this application, the term “and/or” is a kind of association relationship describing the relationship between associated objects, which means that there can be three kinds of relationships. For example, A and/or B can indicate that A exists alone, A and B exist simultaneously, and B exists alone. In addition, the character “/” in this application generally indicates that the contextual associated objects belong to an “and/or” relationship.

In this application, the terms “connection”, “combination”, “coupling” and “installation” may be direct connection, combination, coupling or installation, and may also be indirect connection, combination, coupling or installation. Among them, for example, direct connection means that two members or assemblies are connected together without intermediaries, and indirect connection means that two members or assemblies are respectively connected with at least one intermediate members and the two members or assemblies are connected by the at least one intermediate members. In addition, “connection” and “coupling” are not limited to physical or mechanical connections or couplings, and may include electrical connections or couplings.

In this application, it is to be understood by those skilled in the art that a relative term (such as “about”, “approximately”, and “substantially”) used in conjunction with quantity or condition includes a stated value and has a meaning dictated by the context. For example, the relative term includes at least a degree of error associated with the measurement of a particular value, a tolerance caused by manufacturing, assembly, and use associated with the particular value, and the like. Such relative term should also be considered as disclosing the range defined by the absolute values of the two endpoints. The relative term may refer to plus or minus of a certain percentage (such as 1%, 5%, 10%, or more) of an indicated value. A value that did not use the relative term should also be disclosed as a particular value with a tolerance. In addition, “substantially” when expressing a relative angular position relationship (for example, substantially parallel, substantially perpendicular), may refer to adding or subtracting a certain degree (such as 1 degree, 5 degrees, 10 degrees or more) to the indicated angle.

In this application, those skilled in the art will understand that a function performed by an assembly may be performed by one assembly, multiple assemblies, one member, or multiple members. Likewise, a function performed by a member may be performed by one member, an assembly, or a combination of members.

In this application, the terms “up”, “down”, “left”, “right”, “front”, and “rear” and other directional words are described based on the orientation or positional relationship shown in the drawings, and should not be understood as limitations to the examples of this application. In addition, in this context, it also needs to be understood that when it is mentioned that an element is connected “above” or “under” another element, it can not only be directly connected “above” or “under” the other element, but can also be indirectly connected “above” or “under” the other element through an intermediate element. It should also be understood that orientation words such as upper side, lower side, left side, right side, front side, and rear side do not only represent perfect orientations, but can also be understood as lateral orientations. For example, lower side may include directly below, bottom left, bottom right, front bottom, and rear bottom.

In this application, the terms “controller”, “processor”, “central processor”, “CPU” and “MCU” are interchangeable. Where a unit “controller”, “processor”, “central processing”, “Central Processing Unit (CPU)”, or “Microcontroller Unit (MCU)” is used to perform a specific function, the specific function may be implemented by a single aforementioned unit or a plurality of the aforementioned unit.

In this application, the term “device”, “module” or “unit” may be implemented in the form of hardware or software to achieve specific functions.

In this application, the terms “computing”, “judging”, “controlling”, “determining”, “recognizing” and the like refer to the operations and processes of a computer system or similar electronic computing device (e.g., controller, processor, etc.).

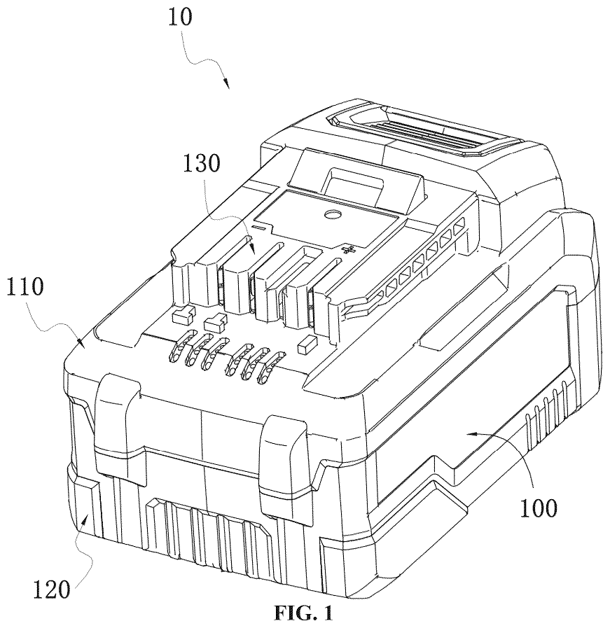

As shown in FIGS. 1 & 2, a battery or battery pack 10 is illustrated in this application. The battery pack 10 can be configured for transferring power to and receiving power from one or more electrical devices, such as a power tool, a battery charger and the like. The battery pack 10 can power a wide range of power tools including a driver drill, an impact wrench, a right-angle drill, a reciprocating saw, a circular saw, a band saw, a table saw, a work light, a rotary hammer, a nail gun, a blower, a vacuum blower, a lawn mower, a snow thrower and the like.

The battery pack 10 can have any battery chemistry such as lead-acid, Nickel-cadmium (“NiCd”), Nickel-Metal Hydride (“NiMH”), Lithium (“Li”), Lithium-ion (“Li-ion”), another Lithium-based chemistry or another rechargeable or non-rechargeable battery chemistry. In the illustrated examples, the battery can have a battery chemistry of Li, Li-ion or another Li-based chemistry and can supply an average discharge current that is equal to or greater than approximately 20 A. For example, in the illustrated construction, the battery pack 10 can have a chemistry of Lithium Cobalt (“Li—Co”), Lithium Manganese (“Li—Mn”) Spinel, or Li—Mn Nickel.

The battery pack 10 can also have any nominal voltage. In some examples, the battery pack 10 can have a nominal voltage of approximately 10 V. In some examples, the battery pack 10 can have a nominal voltage up to approximately 60 V. For example, the battery pack 10 can have a nominal voltage of approximately 4 V, 8 V, 12 V, 18 V, 20 V, 24 V, 28 V, 36 V, 48 V, 56 V, etc.

The battery pack 10 can supply an average discharge current that is equal to or greater than approximately 10 A, 15 A or 20 A. The battery pack 10 can have ampere-hour capacity of greater than or equal to 1.3 Ah, 1.5 Ah, 1.8 Ah, 2 Ah, 2.5 Ah, 2.7 Ah, 3 Ah, 3.5 Ah or 4 Ah.

As shown in FIG. 1, the battery pack 10 includes a housing 100 which can provide a terminal supports 130. The battery pack 10 further include a terminal assembly 200 disposed on the housing and supported by the terminal supports 130. The terminal assembly 200 includes one or more terminals and connectable to an electrical device, such as the power tool, the battery charger and the like, as described above. The housing 100 includes an upper housing 110 and a lower housing 120 mating together and form an enclosed space to dispose a plurality of battery cells 140.

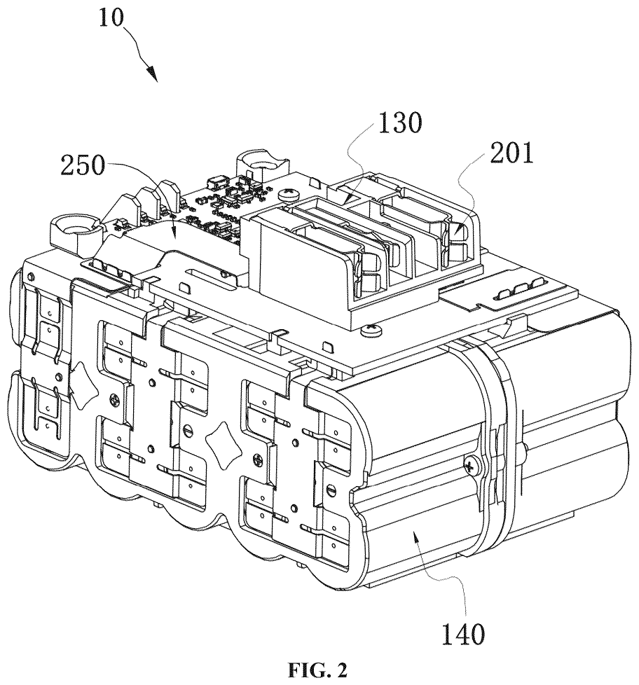

As shown in FIG. 2, the battery pack 10 can include one or more battery cells 140 each having a chemistry and a nominal voltage. Also, each battery cell 140 can include a positive end and a negative end. In some examples, two or more battery cells 140 can be arranged in series with the positive end of one battery cell 140 electrically connected to the negative end of another battery cell 140. In some examples, the battery cells 140 can be arranged in parallel with the positive ends of the battery cells electrically connected to each other and the negative ends of the battery cells electrically connected to each other. In some examples, two or more battery cells 140 can be arranged in a combination of series and parallel.

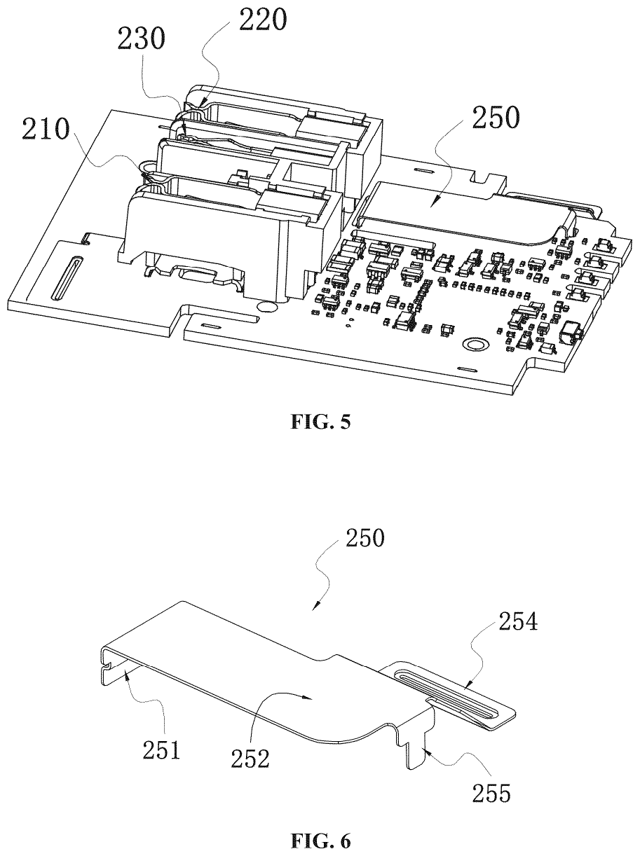

As shown in FIGS. 1-10, the terminal assembly 200 is disposed on the housing 100 for electrically connecting the battery pack 10 to the power tool. In the illustrated construction, the terminal assembly 200 includes one or more battery terminals 201, such as a positive terminal 210, a negative terminal 220, and a sense terminal 230. The positive terminal 210 can be electrically connected to the positive end of a first battery cell, and the negative terminal 115 can be electrically connected to the negative end of a second battery cell. In some examples, the first battery cell is the first cell of the battery cells 140 to be serially linked, and the second battery cell is the last cell of the battery cells 140 to be serially linked, respectively.

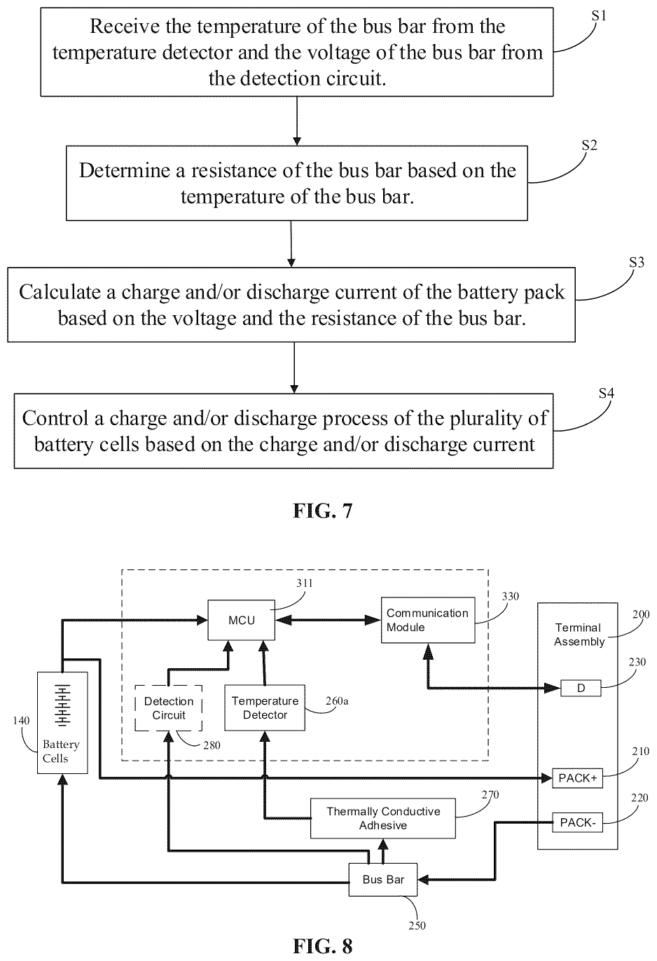

In some examples, the terminals for charging or discharging process could be the same pair of positive terminal 210 and negative 220, as shown in the example of FIGS. 1 to 6. In other examples, the terminals for charging or discharging process could be a different pair of positive terminal 210 and negative 220, as shown in the example of FIGS. 7 to 8. In some examples, the battery pack 10 can also include another pair of positive terminal and negative terminal in addition to the positive terminal 210 and the negative terminal 220. The at least one positive terminals and the at least one negative terminals could be used for different charging and discharging requirements. The terminal assembly 200 can also include another positive terminal in addition to the positive terminal 210. The terminal assembly 200 can also include another negative terminal in addition to the negative terminal 220. In some examples, the terminal assembly 200 can also include another sense terminal in addition to the sense terminal 230. The additional sense terminal can provide another communication path between the electrical device (e.g., power tool, battery charger, and the like) and the battery pack 10.

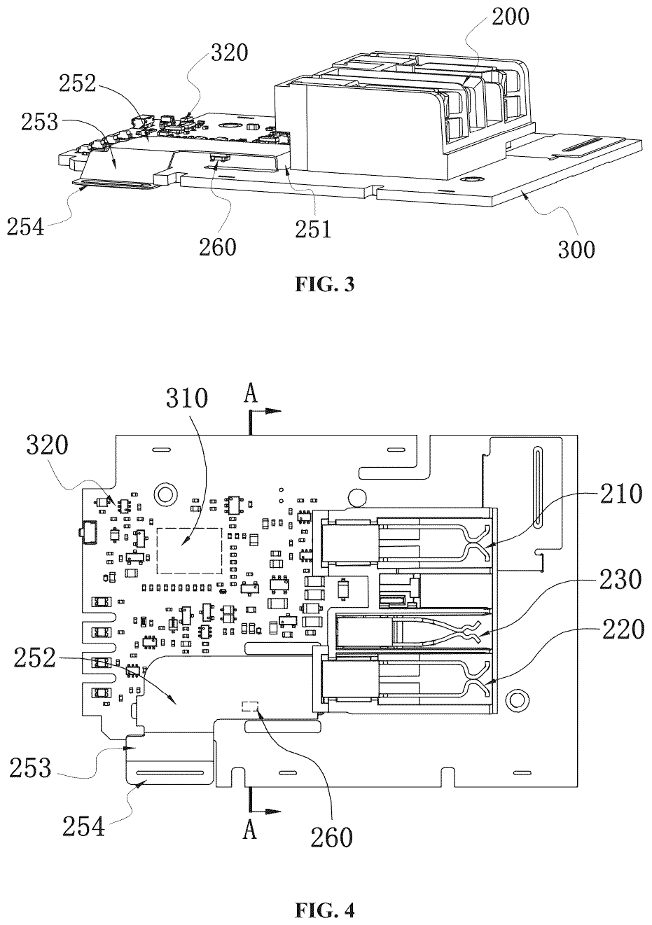

The housing 100 can substantially enclose a control circuit (in FIG. 8) electrically connected to the terminal assembly 200. The control circuit may include a controller 310 (as shown in FIGS. 3 & 4). The controller 310 is configured of, for example, a CPU and a memory, a MCU 311, or a microcomputer. In some examples, the control circuit can communicate with the electrical devices, such as the power tool, the battery charger, and the like, and can provide information to the devices regarding one or more battery characteristics or conditions, such as the electrical parameters of the battery, the temperature of the battery, the chemistry of the battery and similar characteristics. The similar characteristics or conditions of the device could be the type of device (e.g., power tool, battery charger, and the like), the power, current and/or voltage requirements of the device, thresholds for battery operation, sampling rates, and the like.

The controller 310 can store battery characteristics or battery identification information, such as battery chemistry, nominal voltage, ambient temperature, number of times the battery pack 10 has been charged, the number of times the battery pack 10 has been discharged, various monitoring thresholds, various discharging thresholds, various charging thresholds, and the like, and can store information about the controller 310 itself and its operation, such as frequency and/or number of times battery characteristics have been calculated, number of times the controller 310 disabled the battery pack 10, and the like.

As shown in FIGS. 3 & 4, the battery pack 10 further includes a printed circuit board 300 supported within the housing 100, and the controller 310 is disposed on a printed circuit board 300. The printed circuit board 300 can provide the necessary electrical connections between the controller 310 and the terminal assembly 200, the battery cells 140 and some electrical components 320 included in the battery pack 10. The electrical components 320 could include additional microprocessors, transistors, diodes, current-limiting components, capacitors, etc.

As shown in FIGS. 1-7, the battery pack 10 also includes a bus bar 250 which electrically connects the plurality of battery cells 140 to the positive terminal 210 or the negative terminal 220. The bus bar 250 electrically connects the plurality of battery cells 140 to the negative terminal 220. In the present example, a main material of the bus bar 250 is T2 red copper.

In some examples, an electrical conductivity of the bus bar 250 is greater than or equal to 80%IACS. In some examples, an electrical conductivity of the bus bar 250 is greater than or equal to 85%IACS. In some examples, an electrical conductivity of the bus bar 250 is greater than or equal to 90%IACS. In some examples, an electrical conductivity of the bus bar 250 is greater than or equal to 95%IACS. In some examples, the electrical conductivity of the bus bar 250 could be approximately 83%IACS, 87%IACS, 93%IACS or 97%IACS. In some examples, the electrical conductivity of the bus bar 250 is close to 100%IACS. In some examples, a main material of the bus bar is T2 red copper. Other materials with the electrical conductivity in the above range may also be able to be manufactured as the bus bar 250.

The control circuit includes a detection circuit 280 to detect a voltage of the bus bar 250 is as shown in FIGS. 7-8. When the current flows through the bus bar 250, a pressure drop occurs due to a resistance of the bus bar 250. The controller 310 calculates the current flowing through the negative terminal 220 based on the voltage and temperature supplied from the detection circuit 280. In the present example, the controller 310 includes a memory such that the data of resistance values could be stored and recalled. Multiple resistance values of the bus bar 250 under different temperatures are stored in the memory of the controller 310 in advance. The controller 310 calculates the value of the current flowing through the bus bar 250 by dividing the voltage value between the bus bar 250 provided by the circuit by the resistance of the bus bar 250. The resistance of the bus bar 250 is obtained by recalling in the memory for the resistance value stored at a current temperature of the bus bar 250 detected by a temperature detector 260. As is known in the field, the resistant of the bus bar 250 is changeable with the temperature of the bus bar 250 fluctuates. For example, when the bus bar 250 is at 65 degrees Celsius, a resistance value of the bus bar 250 under 65 degrees Celsius recalled from the memory of the controller 310 will be used to calculate the current flowing through the bus bar 250. As a result, the value of the current flowing through the negative terminal 220 of the battery pack 10 in the charging process or the discharging process can be calculated.

Using the solutions shown above, a resistance error of the bus bar is less than 10%. In some examples, the resistance error of the bus bar is less than 8%. In some examples, the resistance error of the bus bar is less than 6%. In some examples, the resistance error of the bus bar is less than 4%. In some examples, the resistance error of the bus bar could be as low as 2.5%. The calculation of the resistance error is described as follows. First of all, a resistance temperature drift curve is obtained and recorded inside the controller. Take the bus bar 250 at −20 degrees Celsius as an example. A resistance of the bus bar 250 at −20 degrees Celsius which could be obtained from the resistance temperature drift curve will be defined as Value A. A resistance of the bus bar 250 under normal room temperature of 25 degrees Celsius will be defined as Value B. The resistance error at −20 degrees Celsius should be an absolute value of a difference between A and B divided by A.

In one example, an amplifier detection circuit is provided in the detection circuit to amplify the current flowing through the bus bar 250. The detection circuit supplies the controller 310 with a voltage value based on the output voltage of the amplifier detection circuit. Thereby, the controller 310 calculates a value of a current flowing through the battery terminals 201. In other words, the battery pack 10 includes a voltage detector configured to detect a voltage of the bus bar 250. The voltage detector could include an amplifier detection circuit.

The controller 310 is coupled to the detection circuit and the temperature detector 260, or said the controller 310 is electrically connected to the detection circuit and the temperature detector 260. As shown in FIG. 7, the controller 310 is configured to execute the following steps:
Receive the temperature of the bus bar 250 from the temperature detector 260 and the voltage of the bus bar 250 from the detection circuit, as shown in S1.
Determine a resistance of the bus bar 250 based on the temperature of the bus bar 250, as shown in S2.
Calculate a charge and/or discharge current of the battery pack 10 based on the voltage and the resistance of the bus bar 250, as shown in S3.
Control a charge and/or discharge process of the plurality of battery cells based on the charge and/or discharge current, as shown in S4.

The following contents illustrate detailed constructions of the temperature detector 260.

In some examples, the temperature detector 260 could be a thermistor. In other examples, the battery pack 10 can include a thermostat (not shown). The temperature detector 260 can sense the temperature of the bus bar 250 included in the battery pack 10, can sense the temperature of battery pack 10 as a whole, or can sense ambient temperature and the like. In some examples, the resistance value of the temperature detector 260, such as the thermistor, for example, can be indicative of the temperature of the bus bar 250 being sensed and can change as the temperature of the bus bar 250 changes. In some examples, the controller 310 can determine the temperature of the bus bar 250 based on the resistance value of the temperature detector 260. The controller 310 can also monitor the change in temperature verses time by monitoring the temperature detector 260 over time. The controller 310 can also send the temperature information to an electrical device, such as the power tool and/or the battery charger, and/or use the temperature information to initiate certain functions or to control other components within the battery pack 10.

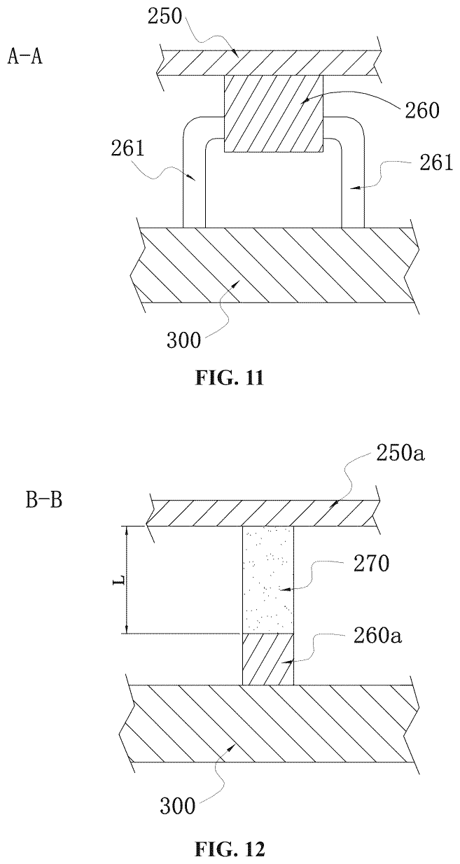

FIGS. 11-12 illustrate two detailed examples to show how the temperature detector 260 is coupled to the bus bar 250. FIG. 11 is a section view of FIG. 4 in A-A direction, and FIG. 12 is a section view of FIG. 10 in B-B direction. FIG. 11 and FIG. 12 shows two heat transferring methods from the temperature detector 260 to the bus bar 250. The main difference between the example in FIGS. 1-6 & 11 (the first example) and the example in FIGS. 8-10 & 12 (the second example) is as follows.

In the first example, the temperature detector 260 is in contact with the bus bar 250 and two leads 261 electrically connect the temperature detector 260 and the printed circuit board 300. That is to say, the temperature detector 260 is mounted on the printed circuit board 300 with one surface touching the bus bar 250. The surface of the temperature detector 260 touching bus bar 250 could be an upper surface or a side surface. The temperature detector 260 could be a diode or a triode, and the PN junction voltage of the diode or triode could be used to estimate the temperature of the temperature detector 260, so as to obtain the temperature of the bus bar 250.

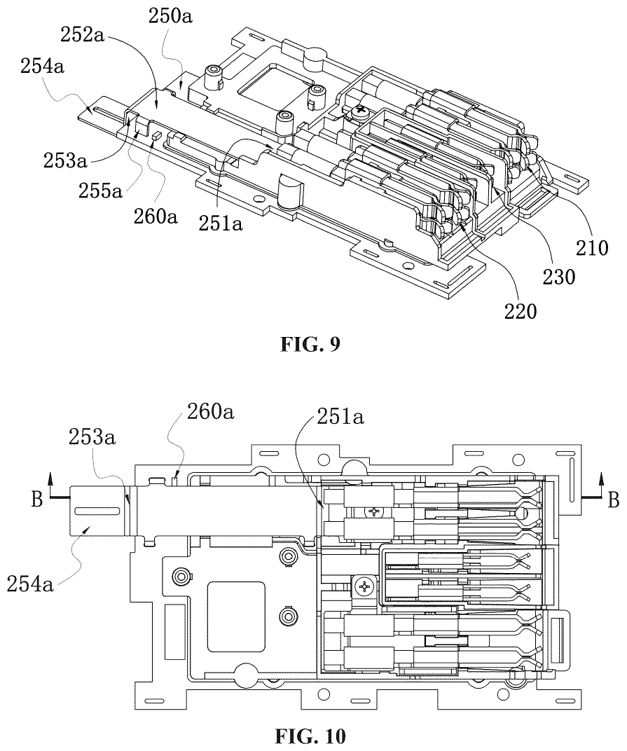

In the second example, the temperature detector 260a could be an NTC thermistor and is adhered to the bus bar 250 by a thermally conductive adhesive 270. The thermally conductive adhesive 270 is not shown in FIGS. 9-10 because of its irregular shape, but shown in FIG. 8 and FIG. 12 for better understanding. The temperature of the NTC can be read in time by the controller 310 or MCU 311 for further calculation.

In the first example, the bus bar 250 has a first connection portion 251, an extension portion 252, at least one lead foot 255, a descending portion 253 and a second connection portion 254. The first connection portion 251 is electrically connected to one of the battery terminals 201. In the present example, the first connection portion 251 is connected to the negative terminal 220. The extension portion 252 extends along the direction of the current, pass through the descending portion 253, and extends all the way down to the second connection portion 254. The second connection portion 254 electrically connected to one of the battery cells 140. And the at least one lead foot 255 fix the bus bar 250 on the printed circuit board 300. In this example, the descending portion 253 forms a slope in respective to the second connection portion 254 because of a height difference between the extension portion 252 and the second connection portion 254. An obtuse angle formed between the descending portion 253 and the second connection portion 254 is greater than or equal to 100 degrees and smaller than or equal to 170 degrees.

In the second example, the bus bar 250a also includes a first connection portion 251a, an extension portion 252a, at least one lead foot 255a, a descending portion 253a and a second connection portion 254a. An angle formed between the descending portion 253a and the second connection portion 254a is approximately a right angle. The at least one lead foot 255 inserted inside the printed circuit board 300 so that the bus bar 250 is fixed on the printed circuit board 300.

In some examples, a distance between the temperature detector 260 and the bus bar is less than or equal to 5 mm. In some examples, a distance between the temperature detector 260 and the bus bar 250 is less than or equal to 3 mm. In some examples, the temperature detector 260 is located in between the printed circuit board 300 and the bus bar 250, as shown in FIGS. 2-12. In some examples, the temperature detector 260 is in direct contact with the bus bar, as shown in FIGS. 3-4 &11. In some examples, the temperature detector 260a is adhered to the bus bar by a thermally conductive adhesive 270, as shown in FIGS. 8-10 &12.

The following contents will introduce some parameters of the bus bar 250 and the thermally conductive adhesive 270.

In some examples, a resistance value of the bus bar 250 under normal room temperature (eg., 25 Degrees Celsius) is less than or equal to 0.18 mΩ. In some examples, a resistance value of the bus bar 250 under normal room temperature (eg., 25 Degrees Celsius) is less than or equal to 0.16 mΩ. In some examples, a resistance value of the bus bar 250 under normal room temperature (eg., 25 Degrees Celsius) is less than or equal to 0.14 mΩ. In some examples, a resistance value of the bus bar 250 under normal room temperature (eg., 25 Degrees Celsius) is less than or equal to 0.12 mΩ. In some examples, a resistance value of the bus bar 250 under normal room temperature (eg., 25 Degrees Celsius) is less than or equal to 0.1 mΩ. It is understandable that all the resistance value listed above should be greater than or equal to 0.

In some examples, a resistance drift rate of the bus bar 250 is less than or equal to 0.5 μΩ/° C. In some examples, a resistance drift rate of the bus bar 250 is less than or equal to 0.48 μΩ/° C. In some examples, a resistance drift rate of the bus bar 250 is less than or equal to 0.47 μΩ/° C. In some examples, a resistance drift rate of the bus bar 250 is less than or equal to 0.46 μΩ/° C. In some examples, a resistance drift rate of the bus bar 250 is less than or equal to 0.45 μΩ/° C.

In some examples, a thermal conductivity of the thermally conductive adhesive 270 is greater than or equal to 0.8 W/(m*K). In some examples, a thermal conductivity of the thermally conductive adhesive is greater than or equal to 1.0 W/(m*K). In some examples, a thermal conductivity of the thermally conductive adhesive is greater than or equal to 1.2 W/(m*K). In some examples, a thermal conductivity of the thermally conductive adhesive is greater than or equal to 1.4 W/(m*K). In some examples, a thermal conductivity of the thermally conductive adhesive is greater than or equal to 1.6 W/(m*K). In some examples, a thermal conductivity of the thermally conductive adhesive is greater than or equal to 1.8 W/(m*K).

In some examples, a volume resistivity of the thermally conductive adhesive is greater than or equal to 1.0*10\hat{ }9(Ω*cm). In some examples, a volume resistivity of the thermally conductive adhesive is greater than or equal to 1.3*10\hat{ }9(Ω*cm). In some examples, a volume resistivity of the thermally conductive adhesive is greater than or equal to 1.6*10\hat{ }9(Ω*cm). In some examples, a volume resistivity of the thermally conductive adhesive is greater than or equal to 1.9*10\hat{ }9(Ω*cm).

The basic principles, main features, and advantages of this application are shown and described above. It is to be understood by those skilled in the art that the aforementioned examples do not limit the present application in any form, and all technical solutions obtained through equivalent substitutions or equivalent transformations fall within the scope of the present application.

What is claimed is:

1. A battery pack, comprising:
a housing connectable to and supportable by a power tool;
a plurality of battery cells supported within the housing;
a terminal assembly disposed on the housing and configured to electrically connect the battery pack to the power tool, the terminal assembly comprising a positive terminal and a negative terminal; and
a bus bar electrically connecting the plurality of battery cells to the positive terminal or the negative terminal;
wherein a resistance value of the bus bar under normal room temperature is less than or equal to 0.18 mΩ, and a resistance drift rate of the bus bar is less than or equal to 0.5 μΩ/° C.

2. The battery pack according to claim 1, wherein a conduction rate of the bus bar is greater than or equal to 80%IACS.

3. The battery pack according to claim 1, wherein a main material of the bus bar is T2 red copper.

4. The battery pack according to claim 1, further comprising a temperature detector configured to detect a temperature of the bus bar.

5. The battery pack according to claim 4, further comprising a detection circuit configured to detect a voltage of the bus bar.

6. The battery pack according to claim 5, further comprising a controller, wherein the controller is configured to:
receive the temperature of the bus bar from the temperature detector and the voltage of the bus bar from the detection circuit;
determine a resistance of the bus bar based on the temperature of the bus bar;
calculate a charge and/or discharge current of the battery pack based on the voltage and the resistance of the bus bar; and
control a charge and/or discharge process of the plurality of battery cells based on the charge and/or discharge current.

7. The battery pack according to claim 4, wherein the temperature detector is an Negative Temperature Coefficient (NTC) thermistor.

8. The battery pack according to claim 4, wherein the temperature detector is adhered to the bus bar by a thermally conductive adhesive.

9. The battery pack according to claim 8, wherein a thermal conductivity of the thermally conductive adhesive is greater than or equal to 0.8 W/(m*K).

10. The battery pack according to claim 4, wherein the temperature detector is in direct contact with the bus bar.

11. The battery pack according to claim 4, wherein a distance between the temperature detector and the bus bar is less than or equal to 5 mm.

12. The battery pack according to claim 4, wherein a distance between the temperature detector and the bus bar is less than or equal to 3 mm.

13. The battery pack according to claim 4, further comprising a printed circuit board supported within the housing, wherein the temperature detector is located between the printed circuit board and the bus bar.

14. The battery pack according to claim 1, wherein a resistance error of the bus bar is less than 10%.

15. The battery pack according to claim 1, wherein a resistance error of the bus bar is less than 6%.

16. A battery pack, comprising:
a housing connectable to and supportable by a power tool;
a plurality of battery cells supported within the housing;
a terminal assembly disposed on the housing and configured to electrically connect the battery pack to the power tool, the terminal assembly comprising a positive terminal and a negative terminal;
a bus bar electrically connecting the plurality of battery cells to the positive terminal or the negative terminal; and
a temperature detector configured to detect a temperature of the bus bar, wherein a distance between the temperature detector and the bus bar is less than or equal to 5 mm.

17. The battery pack according to claim 16, wherein a distance between the temperature detector and the bus bar is less than or equal to 3 mm.

18. The battery pack according to claim 16, wherein the temperature detector is in direct contact with the bus bar.

19. A battery pack, comprising:
a housing connectable to and supportable by a power tool;
a plurality of battery cells supported within the housing;
a terminal assembly disposed on the housing and configured to electrically connect the battery pack to the power tool, the terminal assembly comprising a positive terminal and a negative terminal;
a bus bar electrically connecting the plurality of battery cells to the positive terminal or the negative terminal;
a detection circuit configured to detect a voltage of the bus bar;
a temperature detector configured to detect a temperature of the bus bar; and
a controller coupled to the detection circuit and the temperature detector, the controller being configured to:
receive the temperature of the bus bar from the temperature detector and the voltage of the bus bar from the detection circuit;
determine a resistance of the bus bar based on the temperature of the bus bar;
calculate a charge and/or discharge current of the battery pack based on the voltage and the resistance of the bus bar; and
control a charge and/or discharge process of the plurality of battery cells based on the charge and/or discharge current.

20. The battery pack according to claim 19, wherein a resistance error of the bus bar is less than 10%.
